(19) United States
(12) Patent Application Publication
(10) Pub. No.: US 2026/0013085 A1
(43) Pub. Date: Jan. 8, 2026

(54) DIRECT LIQUID COOLING METHOD, DEVICE, AND COMPUTER PROGRAM FOR SERVER COMPONENTS

(71) Applicant: SAMSUNG SDS CO., LTD., Seoul (KR)

(72) Inventors: In Woo PARK, Seoul (KR); Sang Hun LEE, Seoul (KR); Taehyun KIM, Seoul (KR); Hank W. BAE, Seoul (KR)

(73) Assignee: SAMSUNG SDS CO., LTD., Seoul (KR)

(21) Appl. No.: 19/254,903

(22) Filed: Jun. 30, 2025

(30) Foreign Application Priority Data
Jul. 8, 2024 (KR) 10-2024-0089947
Apr. 11, 2025 (KR) 10-2025-0047387

(51) Int. Cl. H05K 7/20

(52) U.S. Cl. CPC H05K 7/20809

(57) ABSTRACT

A direct liquid cooling method, device, and computer program for server components is proposed, the device providing the uninterrupted and uniform direct liquid cooling for the server components and including a heat sink arranged on top of the server components, a first coolant circulation tube and a second coolant circulation tube that penetrate the heat sink in a transverse direction, a coolant distribution unit for supplying a coolant to the heat sink through the first coolant circulation tube and the second coolant circulation tube, and an upper tunnel space and a lower tunnel space arranged up and down in the traverse direction inside the heat sink, wherein a second coolant, which is a two-phase coolant, is injected into the upper tunnel space and the lower tunnel space.

### CROSS REFERENCE TO RELATED APPLICATION

The present application claims priority to Korean Patent Applications No. 10-2024-0089947, filed Jul. 8, 2024 and No. 10-2025-0047387, filed Apr. 11, 2025, the entire contents of which are incorporated herein for all purposes by this reference.

### BACKGROUND OF THE INVENTION

### Field of the Invention

The present disclosure relates to a direct liquid cooling method, device, and computer program for server components and, more particularly, to a direct liquid cooling method, device, and computer program for server components such as a GPU, a CPU, and a memory of a server and, even more particularly, to a direct liquid cooling method, device, and computer program for server components such as a GPU, a CPU, and a memory of a generative Artificial Intelligence (AI) server.

### Description of the Related Art

Recently, as the use of generative AI increases, the operation of AI servers in data centers is also rapidly increasing. These generative AI servers require a large amount of computation, thereby consuming a lot of electric power and generating high-temperature heat from the main components such as GPUs and CPUs of the servers. Accordingly, in order to effectively lower the high-temperature heat generated from the server components such as GPUs and CPUs, a Direct Liquid Cooling (DLC) method is being utilized, in which cooling is performed by circulating liquid coolants through coolant tubes directly near the high-heat generating server components.

In the direct liquid cooling method, for cooling a generative AI server, a heat sink is installed on the surface of a high-heat generating body and the heat of the high-heat generating body is lowered by directly exchanging heat with a liquid-form circulating coolant. However, the conventional heat-sink cooling method is a single-circuit cooling method, and when a coolant tube is cracked or damaged, the coolant supply is blocked, thereby not only causing the operation of the AI server itself to stop due to a cooling failure of the high-heat generating components (e.g., CPU, GPU, etc.) of the server but also causing the electronic components of the server to be damaged due to coolant leakage. In addition, the simple cooling method using coolant tubes is unable to resolve non-uniform cooling of the heat sink, thereby causing hot spots to occur in the heat sink and resulting in a decrease in the cooling efficiency.

That is, although there is a need for a method that prevents server failure and server component damage caused by coolant leakage and efficiently secures cooling performance by uniformly distributing cold energy to a high-heat generating body, an appropriate solution for these requirements has not yet been proposed.

### SUMMARY OF THE INVENTION

The present disclosure is devised to solve the problems of the related art as described above, and an objective of the present disclosure is to provide a direct liquid cooling method, device, and computer program for server components.

In addition, another objective of the present disclosure is to provide a direct liquid cooling method, device, and computer program for server components, wherein server failure and interruption, which are caused by coolant leakage, may be prevented.

In addition, a yet another objective of the present disclosure is to provide a direct liquid cooling method, device, and computer program for server components, wherein damage to the server components due to coolant leakage may be prevented.

In addition, a still another objective of the present disclosure is to provide a direct liquid cooling method, device, and computer program for server components, wherein cooling performance may be secured by uniformly transferring cold energy to a heat-generating body.

In addition, a still another objective of the present disclosure is to provide a direct liquid cooling method, device, and computer program for server components, wherein direct liquid cooling to a heat-generating body is not interrupted even when a coolant tube is cracked or broken.

In addition, a still another objective of the present disclosure is to provide a direct liquid cooling method, device, and computer program for server components, wherein a coolant in a broken coolant tube can be automatically blocked at a time when the coolant tube is cracked or broken.

The technical problems to be solved in the present disclosure are not limited to the technical problems described above, and other technical problems not described herein may be clearly understood by those skilled in the art to which the present disclosure belongs from the content described in the present specification.

In a first aspect of the present disclosure, there is provided a device for providing uninterrupted direct liquid cooling for server components, the device including: a heat sink arranged on top of the server components; a first coolant circulation tube and a second coolant circulation tube that penetrate the heat sink in a transverse direction; and a coolant distribution unit for supplying a coolant to the heat sink through the first coolant circulation tube and the second coolant circulation tube.

Here, the first coolant circulation tube may penetrate the heat sink in at least one straight path, and the second coolant circulation tube may penetrate the heat sink in at least one straight path.

Here, the first coolant circulation tube may penetrate the heat sink in at least one curved path, and the second coolant circulation tube may penetrate the heat sink in at least one curved path.

Here, in usual times, the coolant may be supplied to the heat sink through the first coolant circulation tube and the second coolant circulation tube, and in a case when coolant circulation of first the coolant circulation tube is interrupted, the coolant may be supplied to the heat sink through the second coolant circulation tube.

Here, the coolant circulation interruption in the first coolant circulation tube may be caused by a crack in the first coolant circulation tube or coolant leakage from the first coolant circulation tube.

Here, the coolant distribution unit may include: a coolant supply unit for supplying the coolant to the heat sink through at least one of the first coolant circulation tube and the second coolant circulation tube; and a coolant recovery unit for recovering the coolant from the heat sink through the at least one of the first coolant circulation tube and the second coolant circulation tube.

Here, the coolant recovery unit may include coolant pressure gauges for measuring pressure inside the coolant tubes in order to check for a crack or coolant leakage in the at least one of the first coolant circulation tube and the second coolant circulation tube, and the coolant supply unit may include coolant block valves for blocking the supplying of the coolant to the at least one of the first coolant circulation tube and the second coolant circulation tube when the pressure is lower than a preset threshold pressure.

In a second aspect of the present disclosure, there is provided a device for providing uniform direct liquid cooling for server components, the device including: a heat sink arranged on top of the server components; and an upper tunnel space and a lower tunnel space arranged up and down in a traverse direction inside the heat sink, wherein a two-phase coolant may be injected into the upper tunnel space and the lower tunnel space.

Here, the device may further include: at least one gaseous-phase coolant flow pipe for connecting the upper tunnel space and the lower tunnel space to each other on at least one of a front and rear of the heat sink; and at least one liquid-phase coolant flow pipe for connecting a lower surface of the upper tunnel space and an upper surface of the lower tunnel space to each other.

Here, a gaseous-phase coolant of the two-phase coolant in the lower tunnel space may move to the upper tunnel space through the at least one gaseous-phase coolant flow pipe, and a liquid-phase coolant of the two-phase coolant in the upper tunnel space may move to the lower tunnel space through the at least one liquid-phase coolant flow pipe.

Here, the at least one gaseous-phase coolant flow pipe may be connected between an upper part of a front or rear of the lower tunnel space and an upper part of a front or rear of the upper tunnel space.

In a third aspect of the present disclosure, there is provided a device for providing uninterrupted and uniform direct liquid cooling for server components, the device including: a heat sink arranged on top of the server components; a first coolant circulation tube and a second coolant circulation tube that penetrate in a traverse direction through the heat sink; a coolant distribution unit for supplying a first coolant to the heat sink through the first coolant circulation tube and the second coolant circulation tube; and an upper tunnel space and a lower tunnel space arranged up and down in the traverse direction inside the heat sink, wherein a second coolant, which is a two-phase coolant, may be injected into the upper tunnel space and the lower tunnel space.

Here, in usual times, the coolant may be supplied to the heat sink through the first coolant circulation tube and the second coolant circulation tube, and in a case when coolant circulation of the first coolant circulation tube is interrupted, the first coolant may be supplied to the heat sink through the second coolant circulation tube.

Here, the coolant circulation interruption in the first coolant circulation tube may be caused by a crack in the first coolant circulation tube or coolant leakage from the first coolant circulation tube.

Here, the coolant distribution unit may include: a coolant supply unit for supplying the first coolant to the heat sink through at least one of the first coolant circulation tube and the second coolant circulation tube; and a coolant recovery unit for recovering the first coolant from the heat sink through the at least one of the first coolant circulation tube and the second coolant circulation tube.

Here, the coolant recovery unit may include coolant pressure gauges for measuring pressure inside the coolant tubes in order to check for a crack or coolant leakage in the at least one of the first coolant circulation tube and the second coolant circulation tube, and the coolant supply unit may include coolant block valves for blocking the supplying of the coolants to the at least one of the first coolant circulation tube and the second coolant circulation tube when the pressure is lower than a preset threshold pressure.

Here, the device may further include: at least one gaseous-phase coolant flow pipe for connecting the upper tunnel space and the lower tunnel space to each other on at least one of a front and rear of the heat sink; and at least one liquid-phase coolant flow pipe for connecting a lower surface of the upper tunnel space and an upper surface of the lower tunnel space to each other.

Here, a gaseous-phase coolant of the two-phase coolant in the lower tunnel space may move to the upper tunnel space through the at least one gaseous-phase coolant flow pipe, and a liquid-phase coolant of the two-phase coolant in the upper tunnel space may move to the lower tunnel space through the at least one liquid-phase coolant flow pipe.

Here, the at least one gaseous-phase coolant flow pipe may be connected between an upper part of a front or rear of the lower tunnel space and an upper part of a front or rear of the upper tunnel space.

Here, the first coolant circulation tube may penetrate the heat sink in at least one straight path, and the second coolant circulation tube may penetrate the heat sink in at least one straight path.

Here, the upper tunnel space and the lower tunnel space may be arranged over the entire length of the heat sink from the front of the heat sink where the first coolant circulation tube and the second coolant circulation tube are introduced to the rear of the heat sink where the first coolant circulation tube and the second coolant circulation tube are withdrawn.

Here, the first coolant circulation tube may penetrate the heat sink in at least one curved path, and the second coolant circulation tube may penetrate the heat sink in at least one curved path.

Here, the device may further include a plurality of the upper tunnel spaces and a plurality of the lower tunnel spaces, wherein some of the plurality of upper tunnel spaces and the plurality of lower tunnel spaces may be arranged over the entire length of the heat sink from the front of the heat sink where the first coolant circulation tube and the second coolant circulation tube are introduced to the rear of the heat sink where the first coolant circulation tube and the second coolant circulation tube are withdrawn, and some others of the plurality of upper tunnel spaces and the plurality of lower tunnel spaces may be arranged over a length from the front of the heat sink where the first coolant circulation tube and the second coolant circulation tube are introduced to an area close to a part where each of the first coolant circulation tube and the second coolant circulation tube bends into one curve, or may be arranged over a length from an area close to a part where each of the first coolant circulation tube and the second coolant circulation tube bends into the other curve to the rear of the heat sink where the first coolant circulation tube and the second coolant circulation tube are withdrawn.

Accordingly, in the direct liquid cooling method, device, and computer program for server components according to an exemplary embodiment of the present disclosure, server failure and interruption, which are caused by coolant leakage, may be prevented.

In addition, in the direct liquid cooling method, device, and computer program for server components according to the exemplary embodiment of the present disclosure, damage to the server components due to coolant leakage may be prevented

In addition, in the direct liquid cooling method, device, and computer program for server components according to the exemplary embodiment of the present disclosure, cooling performance may be secured by uniformly transferring cold energy to a heat-generating body.

In addition, in the direct liquid cooling method, device, and computer program for server components according to the exemplary embodiment of the present disclosure, direct liquid cooling to a heat-generating body may not be interrupted even when a coolant tube is cracked or broken.

In addition, in the direct liquid cooling method, device, and computer program for server components according to the exemplary embodiment of the present disclosure, a coolant in a broken coolant tube can be automatically blocked at a time when the coolant tube is cracked or broken.

The effects obtainable from the present disclosure are not limited to the effects mentioned above, and other effects not mentioned herein will be clearly understood by those skilled in the art to which the present disclosure pertains from the content described in present specification.

### BRIEF DESCRIPTION OF THE DRAWINGS

The accompanying drawings, which are included as part of the detailed description to aid understanding of the present disclosure, provide exemplary embodiments of the present disclosure and describe the technical idea of the present disclosure together with the detailed description.

FIG. 1 is a schematic view illustrating a heat sink of a direct liquid cooling method according to a conventional technology.

FIG. 2 is a schematic view illustrating a device (i.e., a heat sink device for providing uninterrupted cooling) that provides direct liquid cooling to server components according to an exemplary embodiment of the present disclosure.

FIG. 3 is a schematic view illustrating the device (i.e., the heat sink device for providing the uninterrupted cooling) that provides direct liquid cooling to server components according to the exemplary embodiment of the present disclosure.

FIGS. 4A and 4B are plan views each illustrating the device (i.e., the heat sink device for providing the uninterrupted cooling) that provides direct liquid cooling to server components according to the exemplary embodiment of the present disclosure.

FIG. 5 is a plan view, viewed from above, illustrating an arrangement form of coolant tubes of the device (i.e., the heat sink device for providing the uninterrupted cooling) that provides direct liquid cooling to server components according to the exemplary embodiment of the present disclosure.

FIG. 6 is a plan view, viewed from above, illustrating a straight arrangement form of coolant tubes of the device that provides direct liquid cooling for server components according to the exemplary embodiment of the present disclosure.

FIG. 7 is a view illustrating isothermal curves of CPU and GPU chips when coolant tubes are arranged inside a heat sink.

FIG. 8 is a plan view illustrating the device (i.e., the heat sink device for providing the uninterrupted cooling) that provides direct liquid cooling to server components according to the exemplary embodiment of the present disclosure.

FIG. 9 is a front cross-section view illustrating a device (i.e., a heat sink device for providing uniform cooling) that provides direct liquid cooling to server components according to an exemplary embodiment of the present disclosure.

FIG. 10 is a side cross-section view illustrating the device (i.e., the heat sink device for providing the uniform cooling) that provides direct liquid cooling to server components according to the exemplary embodiment of the present disclosure.

FIG. 11 is a side cross-section view illustrating the device (i.e., the heat sink device for providing the uniform cooling) that provides direct liquid cooling to server components according to the exemplary embodiment of the present disclosure.

FIG. 12 is a schematic view illustrating the device (i.e., the heat sink device for providing the uniform cooling) that provides direct liquid cooling to server components according to the exemplary embodiment of the present disclosure.

FIG. 13 is a front cross-section view illustrating a device (i.e., a heat sink device for providing uninterrupted cooling and uniform cooling) that provides direct liquid cooling to server components according to an exemplary embodiment of the present disclosure.

FIG. 14 is a side cross-section view illustrating the device (i.e., the heat sink device for providing the uninterrupted cooling and the uniform cooling) that provides direct liquid cooling to server components according to the exemplary embodiment of the present disclosure.

FIG. 15 is a front cross-section view illustrating a method (i.e., a method for providing uniform cooling) that provides direct liquid cooling to server components according to an exemplary embodiment of the present disclosure.

FIGS. 16A and 16B are front cross-section views each illustrating a method (i.e., a method for providing uninterrupted cooling and uniform cooling) that provides direct liquid cooling to server components according to an exemplary embodiment of the present disclosure.

FIGS. 17A and 17B are conceptual views illustrating the arrangement of uniform cooling devices for each arrangement of coolant tubes according to the exemplary embodiment of the present disclosure.

FIG. 18 is a flowchart illustrating a method (i.e., a direct liquid cooling method for providing uninterrupted cooling) that provides liquid cooling for server components according to an exemplary embodiment of the present disclosure.

FIG. 19 is a flowchart illustrating a method (i.e., a direct liquid cooling method for providing uniform cooling) that provides direct liquid cooling for server components according to an exemplary embodiment of the present disclosure.

FIG. 20 is a view illustrating a device applicable to the proposed method of the present disclosure.

### DETAILED DESCRIPTION OF THE INVENTION

Hereinafter, exemplary embodiments disclosed in the present specification will be described in detail with reference to the attached drawings. Objectives, specific advantages and novel features of the present disclosure will become more apparent from the following detailed description and exemplary embodiments described in conjunction with the accompanying drawings.

The terms and words used in the present specification and claims are appropriately defined by the present inventor to describe his or her own disclosure in the best possible way, and should be interpreted as meanings and concepts that are consistent with the technical idea of the present disclosure, and are only for describing the exemplary embodiments, and should not be interpreted as limiting the present disclosure.

When assigning reference code to components, components that are identical or similar are assigned the same reference code regardless of the reference code, and any duplicate descriptions thereof are omitted. The “module” and “unit and/or part” used as complex words for components in the following description are given or used interchangeably for the sake of ease of specification writing, and do not have distinct meanings or functions in themselves, and may refer to software or hardware components.

In describing the components of the present disclosure, in a case of a component expressed in singular form, it should be understood that the component also includes plural forms unless specifically stated otherwise. In addition, terms such as “first,” “second,” etc. are used to distinguish one component from another, and the components are not limited by these terms. In addition, in a case of a component that is connected to another component, this means that another component may also be connected between that component and a yet another component.

In addition, in describing the exemplary embodiments disclosed in the present specification, when it is determined that a detailed description of a related known technology may obscure the subject matter of the exemplary embodiments disclosed in the present specification, the detailed description thereof will be omitted. In addition, the accompanying drawings are only for easy understanding of the exemplary embodiments disclosed in the present specification, the technical idea disclosed in the present specification is not limited by the accompanying drawings, and it should be understood that the accompanying drawings include all changes, equivalents, or substitutes, which are included in the spirit and technical scope of the present disclosure.

Hereinafter, exemplary embodiments of a direct liquid cooling method, device, and computer program for server components according to the present disclosure are described in detail with reference to the attached drawings.

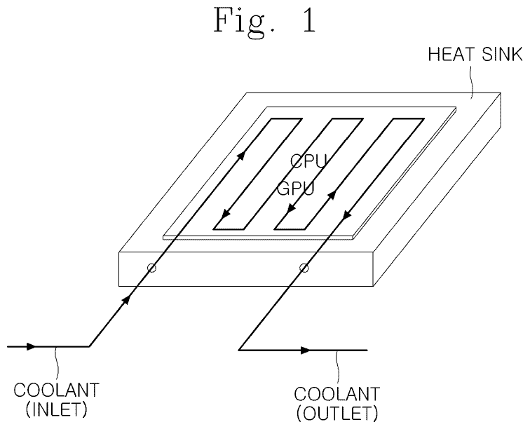

FIG. 1 is a schematic view illustrating a heat sink of a direct liquid cooling method according to a conventional technology.

According to the direct liquid cooling method based on the conventional technology, a heat sink is installed on the surface of high-heat generating components such as a CPU and a GPU in order to cool a generative AI server, and high-temperature heat from a heat-generating body is directly exchanged with a liquid coolant, thereby cooling the generative AI server. However, the existing heat sink cooling method is a single-circuit cooling method, so when a coolant tube is cracked or damaged, coolant supply is blocked, thereby interrupting cooling to the server's high-heat generating body (e.g., the CPU, GPU, etc.). The resulting high temperatures may cause the AI server to stop operating, and damage to server components may also occur due to coolant leakage. In addition, since the cooling method is the method of performing cooling by transferring cold energy through the coolant tube, the cooling of the heat sink may be performed non-uniformly, thereby causing a problem of generating hot spots in the heat sink and reducing cooling efficiency.

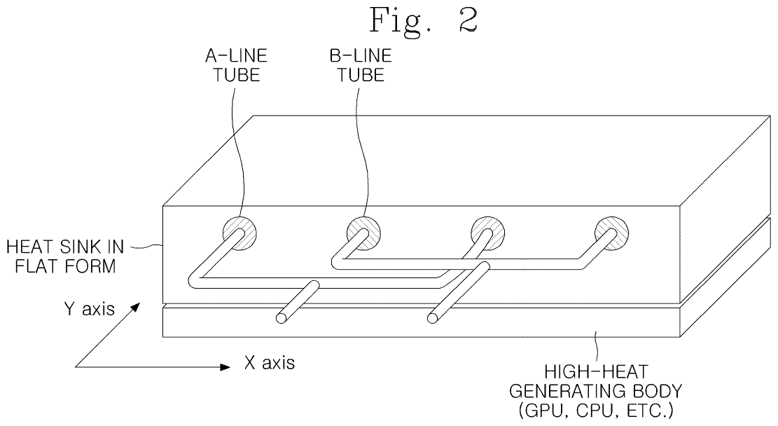

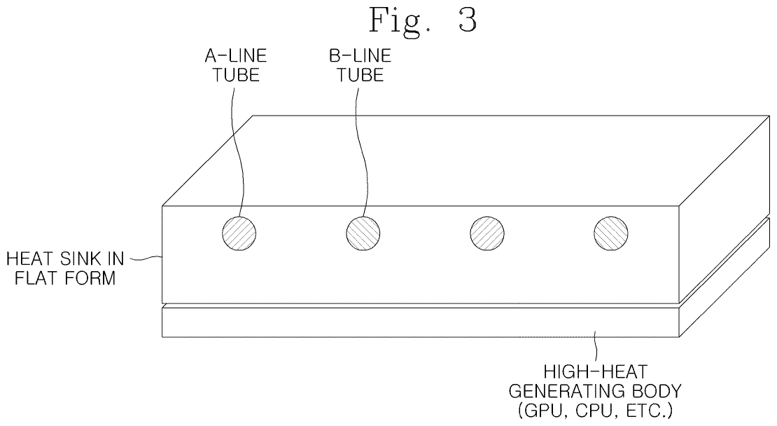

FIGS. 2 and 3 are schematic views each illustrating a device (i.e., a heat sink device for providing uninterrupted cooling) that provides direct liquid cooling to server components according to an exemplary embodiment of the present disclosure. FIG. 2 illustrates the device whose coolant tubes are introduced from outside a heat sink, and FIG. 3 is an example of a device in which coolant tubes introduced from the outside of the heat sink are not shown (represented in cross-section).

The device for providing direct liquid cooling for server components according to the exemplary embodiment of the present disclosure may be a heat sink device providing uninterrupted cooling. In order to provide the uninterrupted cooling, the device for providing direct liquid cooling for server components according to the exemplary embodiment of the present disclosure may provide components, including: dual coolant supply tubes (i.e., an A-line tube and a B-line tube) in case the coolant supply is unavailable (i.e., an occurrence of coolant leakage, etc.) due to a crack or breakage of a coolant tube; a coolant tube pressure gauge for automatically detecting the crack or breakage of the coolant tube; and an automatic locking valve (not shown) for preventing additional refrigerant leakage.

In the device for providing direct liquid cooling for server components according to the exemplary embodiments of the present disclosure, coolant circulation tubes penetrating a heat sink of a high-temperature heat generating body such as a GPU, CPU, and memory in an AI server are configured with dual lines, i.e., Line A and Line B (in the present exemplary embodiments, the two lines, Line A and Line B, are exemplified, but may also be configured with a plurality of two or more lines). In usual times, a coolant circulates through Line A and Line B simultaneously, so as to cool the heat sink. In a case where a problem occurs in Line A due to a crack or leak thereof, coolant circulation in the A-line coolant tube where the problem occurred is stopped, and the coolant in Line B is allowed to be continuously circulated, so as to prevent the AI server from stopping due to high temperature and prevent damage to the server components due to leaked coolant.

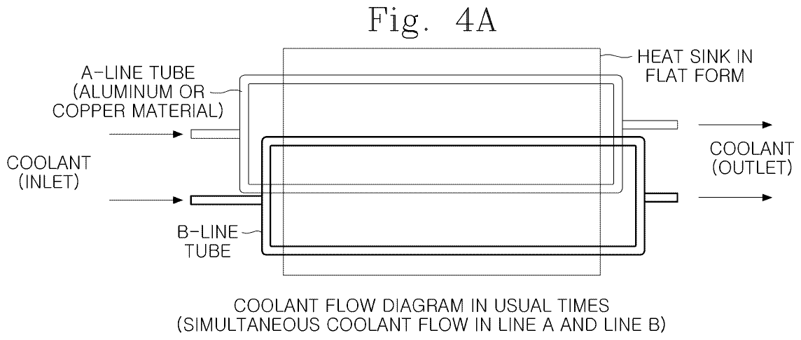

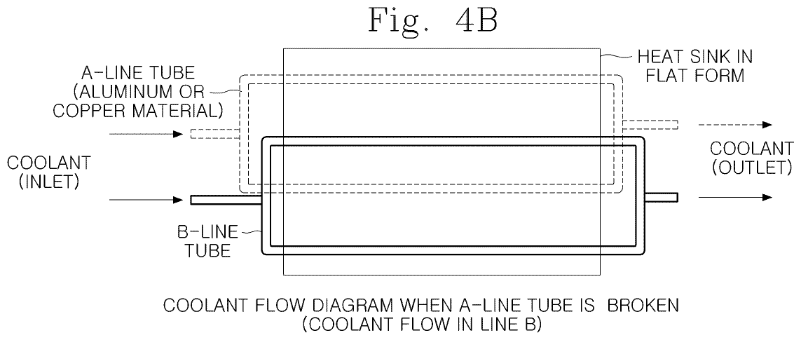

FIGS. 4A and 4B are plan views each illustrating the device (i.e., the heat sink device for providing uninterrupted cooling) that provides direct liquid cooling to server components according to the exemplary embodiment of the present disclosure.

FIGS. 4A and 4B are plan views each illustrating the device (the heat sink device for providing uninterrupted cooling) that provides direct liquid cooling to server components according to the exemplary embodiments of the present disclosure, the plan views being viewed from above in a state where the device is cut along a central horizontal diameter of the coolant tubes.

Coolant (a fluid) circulates inside the heat sink installed on the upper surface of the high-heat generating body such as the GPU and CPU of the AI server so as to exchange heat and the coolant with increased temperature is returned to a Coolant Distribution Unit (CDU) so as to exchange heat with cold water, whereby the high-temperature heat is released to the outside. At this time, when a tube through which the high-temperature coolant circulates and passes through the heat sink installed on the upper surface of the high-heat generating body is damaged or cracked, the electronic components of the server may be damaged due to coolant leakage and the AI server may stop or malfunction.

The coolant circulation tubes penetrating the heat sink for the high-temperature heat generating body such as the AI server's GPU, CPU, and memory are configured to be duplexed with Line A and Line B, so that the coolant circulates through Line A and Line B simultaneously during the normal times, thereby cooling the heat sink. In a case where a crack or leakage occurs in the A-line coolant tube, the coolant circulation in the A-line coolant tube with the malfunction is stopped, and the coolant in Line B is allowed to circulate uninterrupted, so as to prevent the AI server's downtime or failure due to the high temperature.

In FIGS. 4A and 4B, the material of the A-line and B-line coolant tubes penetrating the heat sink of the high-heat generating body is a material that does not react with the coolant, and may be made of aluminum or copper, which has high thermal conductivity similar to that of the heat sink. In contrast, the material of the coolant tubes transmitting the coolant until it penetrates the heat sink may be made of polyethylene or rubber (aluminum or copper may also be used) that does not react with the coolant.

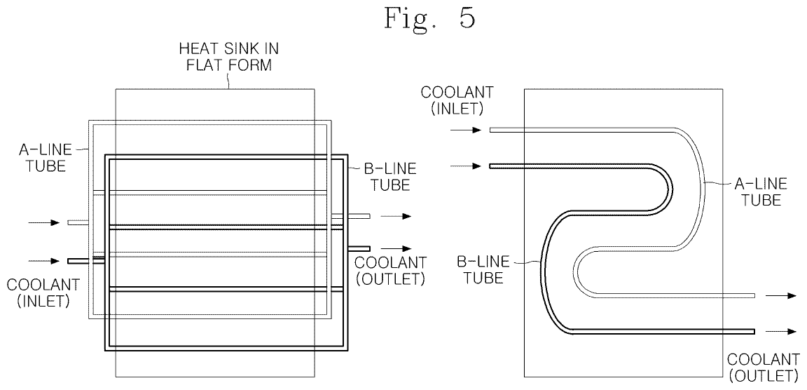

FIG. 5 is a plan view, viewed from above, illustrating an arrangement form of coolant tubes of the device (the heat sink device providing the uninterrupted cooling) that provides direct liquid cooling to server components according to the exemplary embodiment of the present disclosure.

The arrangement form of the coolant tubes, which are configured to be the duplexed A-line and B-line, may have a straight arrangement form and an S-shaped arrangement form for efficient heat transfer.

In the case of the straight arrangement form, flow resistance of coolant is reduced, so a smooth coolant flow may be expected. In the case of the S-shaped arrangement form, there is an advantage in that the coolant tubes may be arranged more simply than in the straight arrangement form.

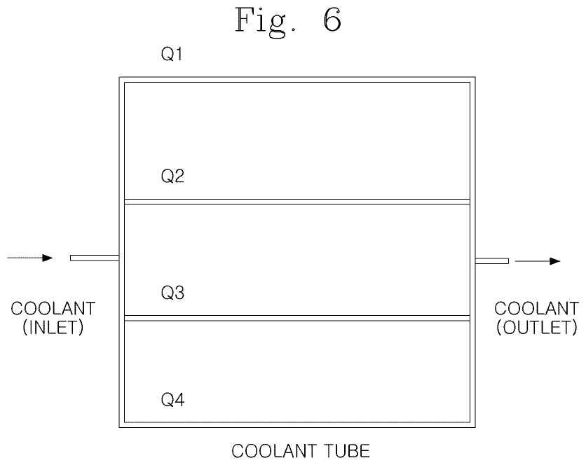

FIG. 6 is a plan view, viewed from above, illustrating a straight arrangement form of coolant tubes of the device that provides direct liquid cooling for server components according to the exemplary embodiment of the present disclosure.

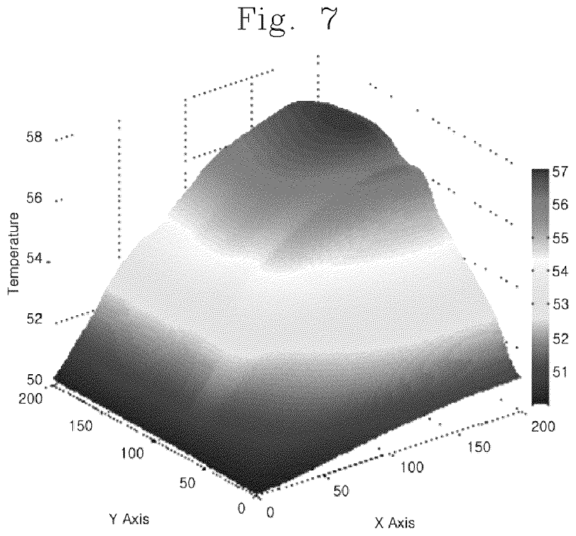

When the coolant tubes are arranged inside the heat sink, a plurality of coolant tubes having the same tube length to opposite ends thereof may be arranged at equal intervals (each of Q1, Q2, Q3, and Q4 is referred to as a quantity of flow of each coolant tube), so that the coolant may be appropriately distributed according to the isothermal curves of CPU and GPU chips (see FIG. 7). The coolant with a large quantity of flow flows at a location close to an inlet tube (pressure loss AP decreases), and as a distance from the inlet tube increases, pressure decreases (pressure loss AP increases), so the coolant with a small quantity of flow is configured to flow in a coolant tube positioned at an edge of the heat sink (i.e., Q2=Q3, Q1=Q4, and Q2>Q1).

As may be seen from the isothermal curves of the CPU or GPU chip in FIG. 7, the center of the chip generates more heat than at each edge. Accordingly, it is preferable to set the quantities of flows (Q2 and Q3) that are of the coolant tubes and flow through the center part of the chip to be greater than the quantities of flows (Q1 and Q4) that are of the coolant tubes and flow through each edge part of the chip.

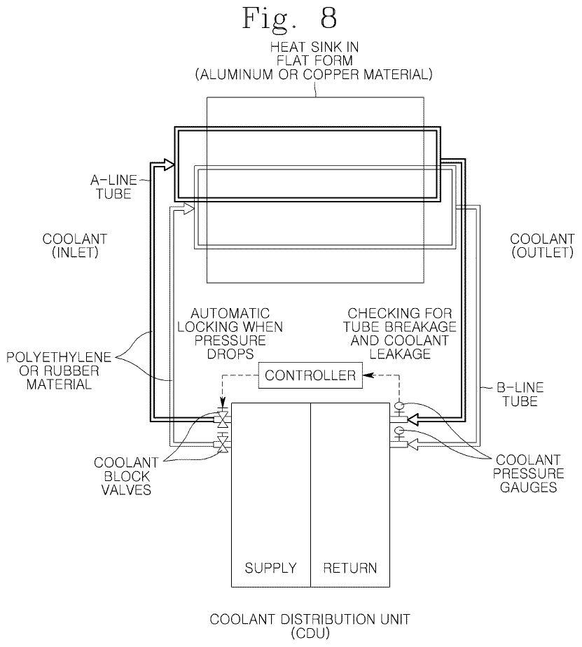

FIG. 8 is a plan view illustrating the device (i.e., the heat sink device for providing uninterrupted cooling) that provides direct liquid cooling to server components according to the exemplary embodiment of the present disclosure.

Coolant pressure gauges installed in the Coolant Distribution Unit (CDU) measure whether a pressure drop in each coolant tube occurs in order to check for coolant tube breakage or coolant leakage. Each coolant block valve blocks a coolant flow from a coolant tube through a controller when a coolant pressure gauge detects an abnormality such as a pressure drop in a coolant tube.

The pressure of a coolant tube is monitored in real time through a pressure gauge connected to the CDUs on a coolant recovery unit (Return) side. In a case where the coolant leaks due to a coolant tube breakage, the pressure on the coolant return side drops, so a coolant block valve on a coolant supply side is controlled to be automatically closed through the controller. Through a coolant tube automatic locking device, damage to the server's electronic components due to the coolant leakage may be prevented.

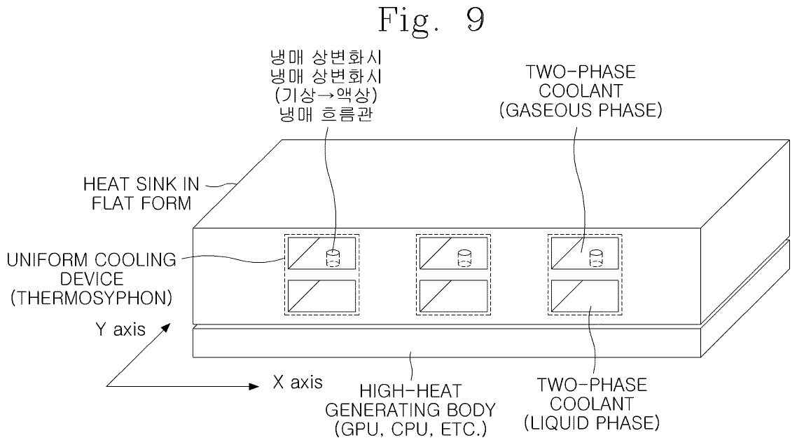

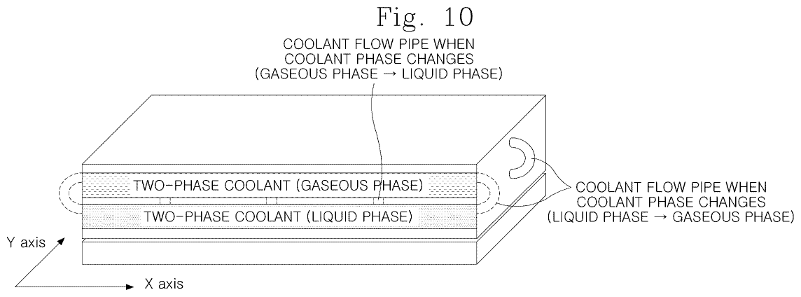

FIG. 9 is a front cross-section view illustrating the device (i.e., the heat sink device for providing uniform cooling) that provides direct liquid cooling to server components according to the exemplary embodiment of the present disclosure. FIG. 10 is a side cross-section view illustrating the device (i.e., the heat sink device for providing the uniform cooling) that provides direct liquid cooling to server components according to the exemplary embodiment of the present disclosure.

The device for providing direct liquid cooling for server components according to the exemplary embodiments of the present disclosure provides uniform cooling by utilizing a thermosiphon phenomenon between a high-heat generating body and a heat sink in an AI server. For example, when the high temperature heat of the heat sink is heat-exchanged with the coolant being circulated through the coolant tubes, the device for providing direct liquid cooling for server components according to the exemplary embodiment of the present disclosure operates so that cold energy is uniformly transferred to the heat sink.

The existing direct liquid cooling method of transferring cold energy through coolant tubes has a problem of non-uniform cooling of a heat sink, causing hot spots to occur on the heat sink and decreasing cooling efficiency. In order to solve such a problem, the device for providing direct liquid cooling for server components according to the exemplary embodiment of the present disclosure uses a two-phase (gas phase and liquid phase) coolant so as to uniformly transfer the cold energy to a high-heat generating body through a thermosiphon action, thereby uniformly cooling the heat sink. That is, the cold energy is transferred non-uniformly from the coolant tubes and is transferred uniformly to the high-heat generating body through coolant phase change (liquid↔gas) of each uniform cooling device.

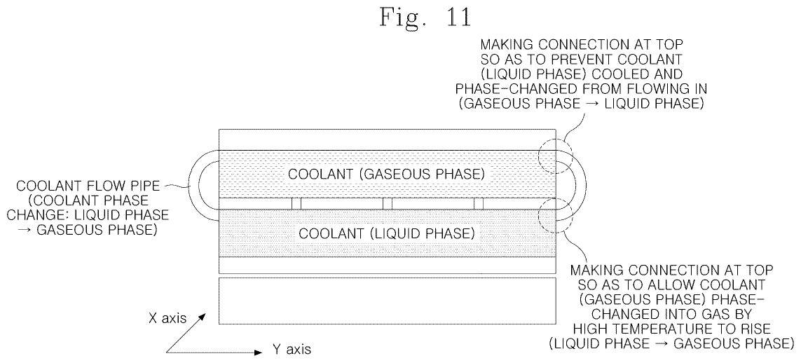

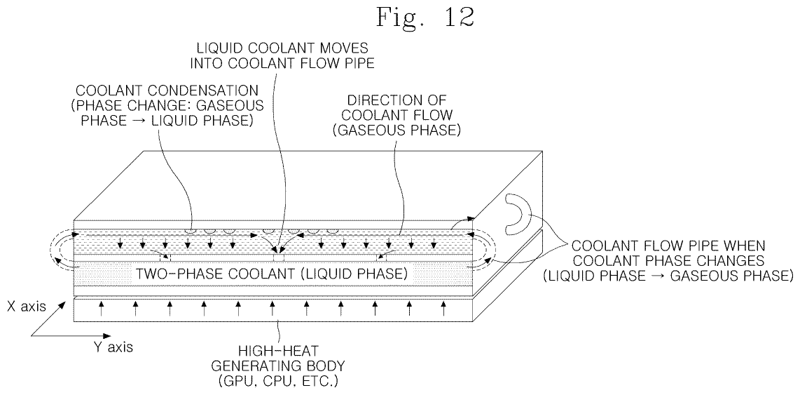

Referring to FIGS. 9 and 10, a lower tunnel space of each uniform cooling device arranged relatively close to a high-heat generating body (GPU, CPU, etc.) is filled with a liquid-phase coolant, so that the high-heat generating body is cooled through this coolant. In addition, the liquid-phase coolant is converted into the gaseous-phase coolant by heat emitted by the high-heat generating body, and then moves to an upper tunnel space of each uniform cooling device positioned relatively far from the high-heat generating body. At this time, as shown in FIG. 10, the coolant converted into the gaseous-phase coolant moves to the upper tunnel space through each gaseous-phase coolant flow pipe, which connected between the upper part of the lower tunnel space and the upper part of the upper tunnel space at the front (or the rear) of the heat sink (described in more detail below on the basis of FIGS. 11 and 12). In addition, as shown in FIG. 10, the coolant that has been converted back into the coolant in the liquid phase by a temperature drop in the upper tunnel space moves to the lower tunnel space through each liquid-phase coolant flow pipe provided between the lower surface of the upper tunnel space and the upper surface of the lower tunnel space, so as to cool the high-heat generating body again (described in more detail below on the basis of FIGS. 11 and 12).

FIG. 11 is a side cross-section view illustrating the device (i.e., the heat sink device for providing the uniform cooling) that provides direct liquid cooling to server components according to the exemplary embodiment of the present disclosure.

Referring to FIG. 11, a liquid-phase coolant in the lower tunnel space is converted into a gaseous-phase coolant due to high temperature, and the coolant (in the gaseous phase) rises to an upper tunnel space through each gaseous-phase coolant flow pipe. At this time, the high-temperature coolant (in the gaseous phase) rises smoothly to the upper tunnel space, and in order to prevent the coolant (in the liquid phase) that has been cooled and condensed in the upper tunnel space from flowing back into each gaseous-phase coolant flow pipe, each gaseous-phase coolant flow pipe is connected between the upper part of the lower tunnel space (i.e., the upper part of the front or rear of the lower tunnel space) and the upper part of the upper tunnel space (i.e., the upper part of the front or rear of the upper tunnel space).

FIG. 12 is a schematic view illustrating the device (i.e., the heat sink device for providing the uniform cooling) that provides direct liquid cooling to server components according to the exemplary embodiment of the present disclosure.

Referring to FIG. 12, a liquid-phase coolant in a lower tunnel space receives heat from a high-heat generating body, so as to be phase-changed into a gas, and moves to an upper tunnel space (i.e., a coolant condensation area in the upper part thereof) through each gaseous-phase coolant flow pipe. Repetitive circulation is operated in a way where the coolant is phase-changed back to a liquid through heat exchange (e.g., heat exchange with coolant tubes) in the coolant condensation area and moves to the lower tunnel space (i.e., a liquid-phase coolant area of the lower part thereof) through each liquid-phase coolant flow pipe, thereby cooling the high-heat generating body uniformly.

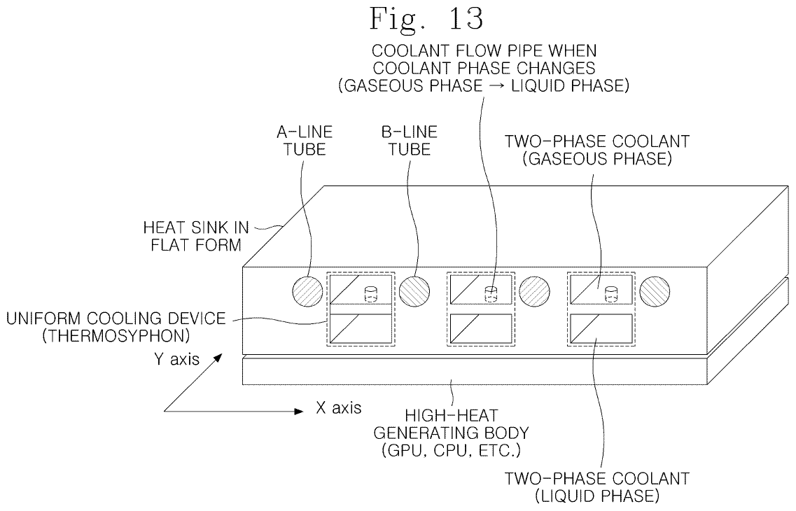

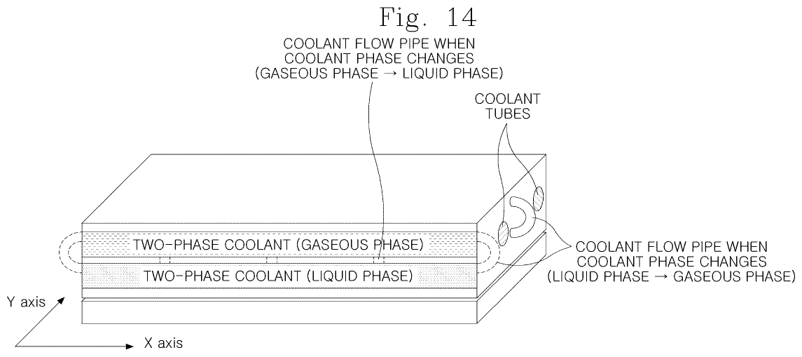

FIG. 13 is a front cross-section view illustrating the device (i.e., the heat sink device for providing the uninterrupted cooling and the uniform cooling) that provides direct liquid cooling to server components according to the exemplary embodiment of the present disclosure. FIG. 14 is a side cross-section view illustrating the device (i.e., the heat sink device for providing the uninterrupted cooling and the uniform cooling) that provides direct liquid cooling to server components according to the exemplary embodiment of the present disclosure.

The device for providing direct liquid cooling for server components according to the exemplary embodiment of the present disclosure provides uniform cooling by utilizing a thermosiphon phenomenon between a high-heat generating body and a heat sink in an AI server. For example, when the high temperature heat of the heat sink is heat-exchanged with the coolant circulated through the coolant tubes, the device for providing direct liquid cooling for server components according to the exemplary embodiment of the present disclosure operates so that cold energy is uniformly transferred to the heat sink. That is, the cold energy is transferred non-uniformly from a coolant tube, and then is transferred uniformly to the high-heat generating body through the coolant phase change (liquid↔gas) of each uniform cooling device.

Each uniform cooling device's lower tunnel space positioned relatively close to the high-heat generating body (GPU, CPU, etc.) is filled with the liquid-phase coolant, so that the high-heat generating body is cooled through this coolant. In addition, the liquid-phase coolant is converted into the gaseous-phase coolant by heat emitted by the high-heat generating body, and then moves to each uniform cooling device's upper tunnel space positioned relatively far from the high-heat generating body. At this time, the coolant that has been converted back into the liquid-phase coolant due to cooling by the coolant tubes in the upper tunnel space moves to the lower tunnel space through each liquid-phase coolant flow pipe provided between the lower surface of the upper tunnel space and the upper surface of the lower tunnel space, thereby cooling the high-heat generating body again. That is, the liquid-phase coolant in the lower tunnel space receives heat from the high-heat generating body, is phase-changed into a gas, and moves to the upper tunnel space (i.e., a coolant condensation area in the upper part) through each gaseous-phase coolant flow pipe, so that repetitive circulation is operated in a way where the coolant is phase-changed back to a liquid through heat exchange with the cold coolant tubes in the coolant condensation area and is moved to the lower tunnel space (i.e., a liquid-phase coolant area in the lower part) through each liquid-phase coolant flow pipe, thereby cooling the high-heat generating body uniformly.

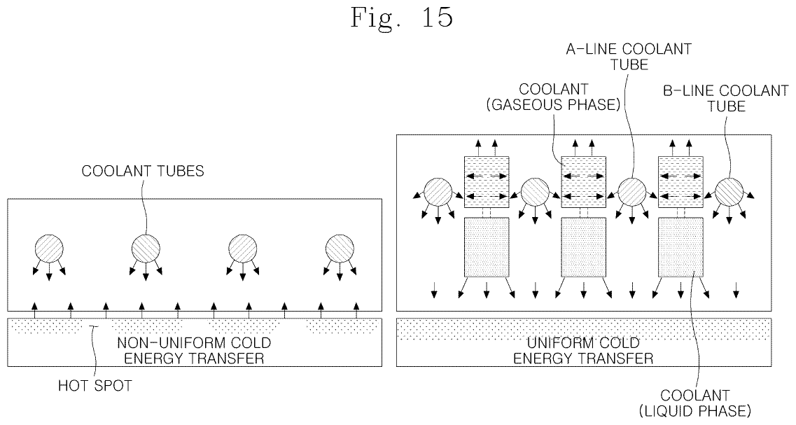

FIG. 15 is a front cross-section view illustrating the device (i.e., the heat sink device for providing the uniform cooling) that provides direct liquid cooling to server components according to the exemplary embodiment of the present disclosure.

FIG. 15 shows the process of transferring cold energy through a thermosiphon action of each uniform cooling device for a heat sink. A coolant used in each uniform cooling device uses a two-phase (gaseous phase and liquid phase) coolant. Each uniform cooling device receives the cold energy non-uniformly from coolant tubes and transfers the cold energy to a high-heat generating body through coolant phase change of each uniform cooling device.

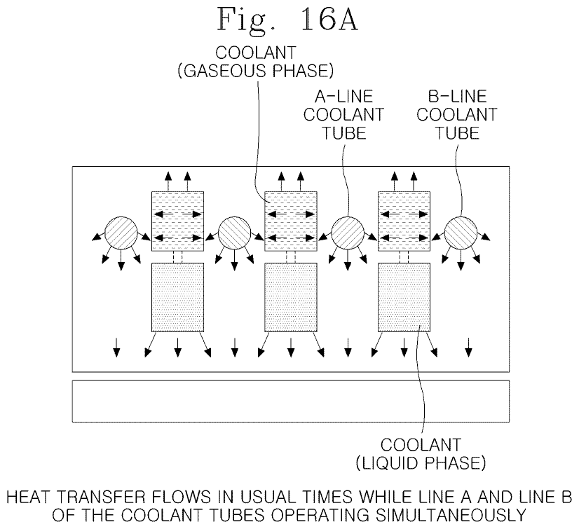

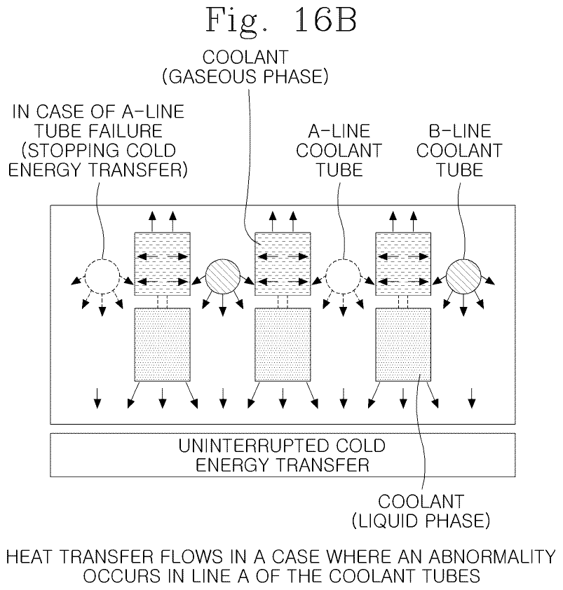

FIGS. 16A and 16B are front cross-section views each illustrating the device (i.e., the heat sink device for providing uniform cooling and uninterrupted cooling) that provides direct liquid cooling to server components according to the exemplary embodiment of the present disclosure.

FIG. 16A shows a heat transfer flow in a normal state of each coolant tube in usual times while Line A and Line B of the coolant tubes operating simultaneously. FIG. 16B shows heat transfer flows in a case where an abnormality occurs in either Line A or Line B of the coolant tubes. Even when the abnormality occurs in either Line A or Line B of the coolant tubes, since the coolant circulation is duplexed, cold energy is continuously and uniformly transferred to a high-heat generating body.

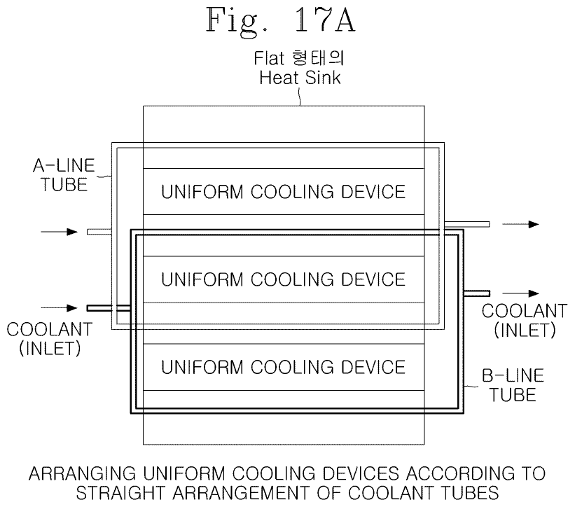

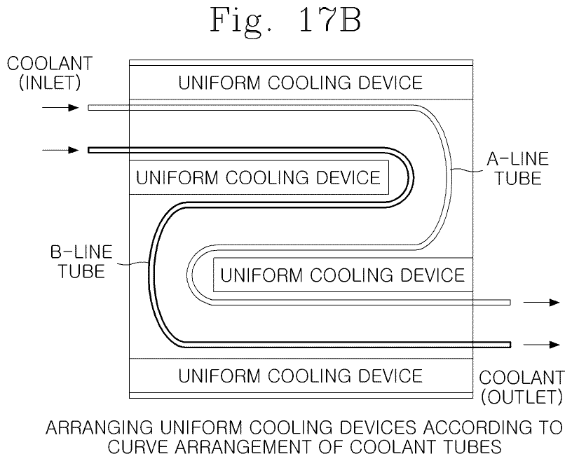

FIGS. 17A and 17B are conceptual views illustrating the arrangement of uniform cooling devices for each arrangement of coolant tubes according to the exemplary embodiment of the present disclosure.

FIG. 17A shows a form in which uniform cooling devices are arranged straight according to the straight arrangement of the coolant tubes. The uniform cooling devices are placed in the form of being inserted into respective spaces formed between the coolant tubes placed in straight arrangement. Accordingly, the uniform cooling devices may be installed along the entire length of a heat sink from the front of the heat sink where the coolant tubes are introduced to the rear of the heat sink where the coolant tubes are withdrawn.

FIG. 17B shows a form in which uniform cooling devices are arranged according to the curved arrangement of coolant tubes. The uniform cooling devices are placed in the form of being inserted into respective in-between spaces formed by each coolant tube placed in curved arrangement. Accordingly, some of a plurality of uniform cooling devices may be installed over the entire length from the front where the coolant tubes are introduced to the rear where the coolant tubes are withdrawn. However, some others of the plurality of uniform cooling devices may be installed over a length from the front where a coolant tube is introduced to an area close to a part where each coolant tube bends into one curve (or a U-shape), or may be installed over a length from an area close to a part where each coolant tube bends into the other curve (or a U-shape) to the rear where the coolant tube is withdrawn.

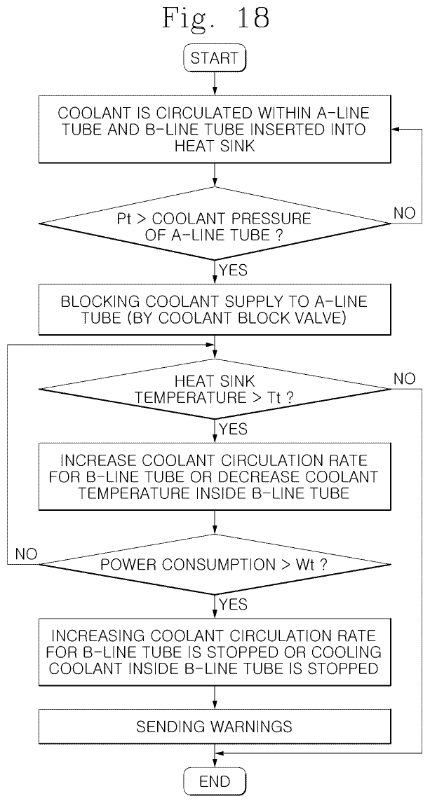

FIG. 18 is a flowchart illustrating a method (i.e., a direct liquid cooling method for providing uninterrupted cooling) for providing direct liquid cooling for server components according to the exemplary embodiment of the present disclosure.

Referring to FIG. 18, in a state while a coolant in A-line and B-line tubes inserted into a heat sink is circulating, when the pressure of a coolant pressure gauge for the A-line tube installed in a Coolant Distribution Unit (CDU) is measured to be lower than a preset threshold pressure Pt, coolant supply to the A-line tube is blocked by a coolant block valve. Due to this, only the B-line tube is caused to perform coolant circulation.

At this time, in a case where the temperature of the heat sink is measured to have a value higher than that of a preset critical temperature Tt due to the performing of the coolant circulation operation only through the B-line tube, a coolant circulation rate of the B-line tube may be controlled to increase or the temperature of the coolant inside the B-line tube may be controlled to decrease.

In addition, in a case where power consumption due to the increase in the coolant circulation rate for the B-line tube or the decrease in the coolant temperature inside the B-line tube is measured to have a value higher than that of a preset threshold power Wt, increasing the coolant circulation rate for the B-line tube or decreasing the coolant temperature inside the B-line tube may be stopped. At this time, warnings may also be sent for the cases including: the excessive power consumption; the stopped increase of the coolant circulation rate for the B-line tube; and the stopped decrease of the coolant temperature inside the B-line tube.

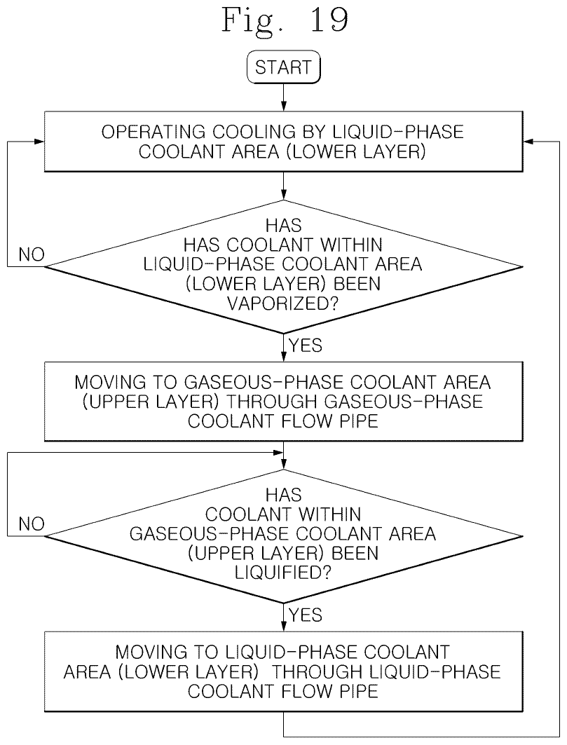

FIG. 19 is a flowchart illustrating a method (i.e., a direct liquid cooling method for providing uniform cooling) that provides direct liquid cooling for server components according to an exemplary embodiment of the present disclosure.

Referring to FIG. 19, during cooling operation using a liquid-phase coolant in a lower tunnel space (i.e., a liquid-phase coolant area), the liquid-phase coolant may be converted into a gaseous-phase coolant by heat of a high-heat generating body. At this time, the gaseous-phase coolant moves to an upper tunnel space (i.e., a gaseous-phase coolant area) through each gaseous-phase coolant flow pipe, and when being condensed and liquefied in the upper tunnel space, the gaseous-phase coolant moves to the lower tunnel space (i.e., the liquid-phase coolant area) through each liquid-phase coolant flow pipe. Then, cooling is achieved by the liquid-phase coolant within the lower tunnel space (the liquid-phase coolant area).

Device Applicable with Proposed of Present Disclosure

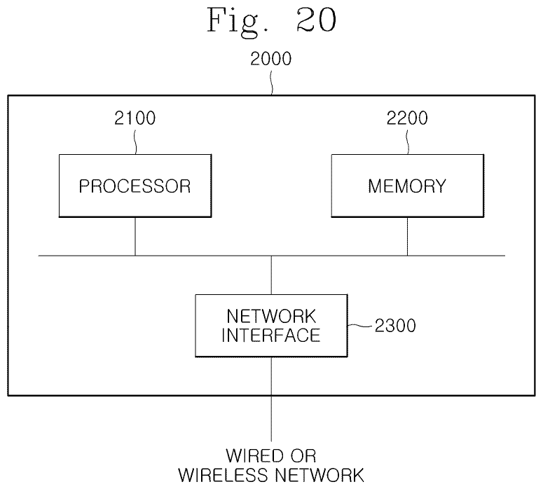

FIG. 20 is a view illustrating a device 2000 applicable to the proposed method of the present disclosure. A server, a terminal, or the like that performs a direct liquid cooling method for server components may correspond to the device 2000.

Referring to FIG. 20, the device 2000 may be a server device or a terminal device, which is configured to implement a process for the direct liquid cooling method for the server components.

For example, the device 2000 to which the proposed method of the present disclosure is applicable may include: network devices such as repeaters, hubs, bridges, switches, routers, and gateways; computer devices such as desktop computers and workstations; mobile terminals such as smartphones; portable devices such as laptop computers; home appliances such as digital TVs; and mobility means such as automobiles. As another example, a device 2000 to which the present disclosure is applicable may be included as part of an Application Specific Integrated Circuit (ASIC) implemented in the form of a System On Chip (SoC).

The memory 2020 may be connected to the processor 2010 during operation, may store programs and/or instructions for processing and controlling the processor 2010, may store data and information used in the present disclosure, and may control information required for data and information processing according to the present disclosure and control temporary data generated during the data and information processing, etc. The memory 2020 may be implemented as a storage device such as a Read Only Memory (ROM), a Random Access Memory (RAM), an Erasable Programmable Read Only Memory (EPROM), an Electrically Erasable Programmable Read-Only Memory (EEPROM), a flash memory, a Static RAM (SRAM), a Hard Disk Drive (HDD), a Solid State Drive (SSD), etc.

The processor 2010 may be operatively connected to the memory 2020 and the network interface 2030, and controls the operation of each module within the device 2000. In particular, the processor 2010 may perform various control functions for performing the proposed method of the present disclosure. The processor 2010 may also be called a controller, a microcontroller, a microprocessor, a microcomputer, etc. The proposed method of the present disclosure may be implemented by hardware, firmware, software, or a combination thereof. When the present disclosure is implemented by using the hardware, the processor 2010 may be provided with an application specific integrated circuit (ASIC) or a digital signal processor (DSP), a digital signal processing device (DSPD), a programmable logic device (PLD), a field programmable gate array (FPGA), etc., which are configured to perform the present disclosure. Meanwhile, when the proposed method of the present disclosure is implemented by using the firmware or software, the firmware or software may include instructions related to modules, procedures, or functions that perform functions or operations required for implementing the proposed method of the present disclosure, wherein the instructions may be stored in the memory 2020 or be stored in a computer-readable recording medium (not shown) separate from the memory 2020, so as to be configured to cause the device 2000 to implement the proposed method of the present disclosure when executed by the processor 2010.

In addition, the device 2000 may include a network interface device 2030. The network interface device 2030 is connected to the processor 2010 when in operation, so that the processor 2010 controls the network interface device 2030, thereby transmitting or receiving wireless/wired signals carrying information and/or data, signals, messages, and the like through a wireless/wired network. For example, the network interface device 2030 supports various communication standards such as, IEEE 802 series, 3GPP LTE(-A), 3GPP 5G, and may transmit and receive control information and/or data signals according to a relevant communication standard. The network interface device 2030 may also be implemented outside the device 2000 as required.

The above exemplary embodiments and drawings described in the present specification are merely exemplary and do not limit the scope of the present disclosure in any way. In addition, the connection of lines or the members of connection between components shown in the drawings merely exemplify functional connections and/or physical or circuit connections, and an actual device may be represented as a variety of alternative or additional functional connections, physical connections, or circuit connections. In addition, if there is no specific mention such as “essential” or “importantly,” it may not be a component absolutely required for the application of the present disclosure.

In the specification of the present disclosure (especially in the claims), the use of a term “above” and similar referential terms may correspond to both singular and plural usages. In addition, in a case of describing a range in the present disclosure, it is meant to include an embodiment applied with individual values belonging to the range (unless otherwise stated), and is the same as describing each individual value constituting the range in the detailed description of the disclosure. In addition, the steps presented in the method embodiments of the present disclosure are not necessarily intended to be bound by the order of precedence, and the order may be appropriately changed as required, unless a certain step has to come first depending on the nature of each process. The use of all examples or exemplary terminology (for example, “etc.”) in the present disclosure is merely for the purpose of describing the present disclosure in detail, and unless limited by the claims, the scope of the present disclosure is not limited by the above examples or exemplary terminology. In addition, those skilled in the art will appreciate that various modifications, combinations, and changes may be implemented according to design conditions and its elements within the scope of the appended claims or their equivalents.

What is claimed is:

1. A device for providing uninterrupted direct liquid cooling for server components, the device comprising:
a heat sink arranged on top of the server components;
a first coolant circulation tube and a second coolant circulation tube that penetrate the heat sink in a transverse direction; and
a coolant distribution unit for supplying a coolant to the heat sink through the first coolant circulation tube and the second coolant circulation tube.

2. The device of claim 1, wherein the first coolant circulation tube penetrates the heat sink in at least one straight path, and
the second coolant circulation tube penetrates the heat sink in at least one straight path.

3. The device of claim 1, wherein the first coolant circulation tube penetrates the heat sink in at least one curved path, and
the second coolant circulation tube penetrates the heat sink in at least one curved path.

4. The device of claim 1, wherein in usual times, the coolant is supplied to the heat sink through the first coolant circulation tube and the second coolant circulation tube, and
in a case when coolant circulation of the first coolant circulation tube is interrupted, the coolant is supplied to the heat sink through the second coolant circulation tube.

5. The device of claim 4, wherein the coolant circulation interruption in the first coolant circulation tube is caused by a crack in the first coolant circulation tube or coolant leakage from the first coolant circulation tube.

6. The device of claim 1, wherein the coolant distribution unit comprises:
a coolant supply unit for supplying the coolant to the heat sink through at least one of the first coolant circulation tube and the second coolant circulation tube; and
a coolant recovery unit for recovering the coolant from the heat sink through the at least one of the first coolant circulation tube and the second coolant circulation tube.

7. The device of claim 6, wherein the coolant recovery unit comprises:
coolant pressure gauges for measuring pressure inside the coolant tubes in order to check for a crack or coolant leakage in the at least one of the first coolant circulation tube and the second coolant circulation tube, and
the coolant supply unit comprises:
coolant block valves for blocking the supplying of the coolant to the at least one of the first coolant circulation tube and the second coolant circulation tube when the pressure is lower than a preset threshold pressure.

8. A device for providing uniform direct liquid cooling for server components, the device comprising:
a heat sink arranged on top of the server components; and
an upper tunnel space and a lower tunnel space arranged up and down in a traverse direction inside the heat sink,
wherein a two-phase coolant is injected into the upper tunnel space and the lower tunnel space.

9. The device of claim 8, further comprising:
at least one gaseous-phase coolant flow pipe for connecting the upper tunnel space and the lower tunnel space to each other on at least one of a front and rear of the heat sink; and
at least one liquid-phase coolant flow pipe for connecting a lower surface of the upper tunnel space and an upper surface of the lower tunnel space to each other.

10. The device of claim 9, wherein a gaseous-phase coolant of the two-phase coolant in the lower tunnel space moves to the upper tunnel space through the at least one gaseous-phase coolant flow pipe, and
a liquid-phase coolant of the two-phase coolant in the upper tunnel space moves to the lower tunnel space through the at least one liquid-phase coolant flow pipe.

11. The device of claim 10, wherein the at least one gaseous-phase coolant flow pipe is connected between an upper part of a front or rear of the lower tunnel space and an upper part of a front or rear of the upper tunnel space.

12. A device for providing uninterrupted and uniform direct liquid cooling for server components, the device comprising:
a heat sink arranged on top of the server components;
a first coolant circulation tube and a second coolant circulation tube that penetrate in a traverse direction through the heat sink;
a coolant distribution unit for supplying a first coolant to the heat sink through the first coolant circulation tube and the second coolant circulation tube; and
an upper tunnel space and a lower tunnel space arranged up and down in the traverse direction inside the heat sink,
wherein a second coolant, which is a two-phase coolant, is injected into the upper tunnel space and the lower tunnel space.

13. The device of claim 12, wherein in usual times, the coolant is supplied to the heat sink through the first coolant circulation tube and the second coolant circulation tube, and
in a case when coolant circulation of the first coolant circulation tube is interrupted, the first coolant is supplied to the heat sink through the second coolant circulation tube.

14. The device of claim 13, wherein the coolant circulation interruption in the first coolant circulation tube is caused by a crack in the first coolant circulation tube or coolant leakage from the first coolant circulation tube.

15. The device of claim 12, wherein the coolant distribution unit comprises:
a coolant supply unit for supplying the first coolant to the heat sink through at least one of the first coolant circulation tube and the second coolant circulation tube; and
a coolant recovery unit for recovering the first coolant from the heat sink through the at least one of the first coolant circulation tube and the second coolant circulation tube.

16. The device of claim 15, wherein the coolant recovery unit comprises:
coolant pressure gauges for measuring pressure inside the coolant tubes in order to check for a crack or coolant leakage in the at least one of the first coolant circulation tube and the second coolant circulation tube, and
the coolant supply unit comprises:
coolant block valves for blocking the supplying of the coolants to the at least one of the first coolant circulation tube and the second coolant circulation tube when the pressure is lower than a preset threshold pressure.

17. The device of claim 12, further comprising:
at least one gaseous-phase coolant flow pipe for connecting the upper tunnel space and the lower tunnel space to each other on at least one of a front and rear of the heat sink; and
at least one liquid-phase coolant flow pipe for connecting a lower surface of the upper tunnel space and an upper surface of the lower tunnel space to each other.

18. The device of claim 17, wherein a gaseous-phase coolant of the two-phase coolant in the lower tunnel space moves to the upper tunnel space through the at least one gaseous-phase coolant flow pipe, and
a liquid-phase coolant of the two-phase coolant in the upper tunnel space moves to the lower tunnel space through the at least one liquid-phase coolant flow pipe.

19. The device of claim 18, wherein the at least one gaseous-phase coolant flow pipe is connected between an upper part of a front or rear of the lower tunnel space and an upper part of a front or rear of the upper tunnel space.

20. The device of claim 12, wherein the first coolant circulation tube penetrates the heat sink in at least one straight path or at least one curved path, and
the second coolant circulation tube penetrates the heat sink in at least one straight path or at least one curved path.
